(19) United States
(12) Patent Application Publication
(10) Pub. No.: US 2025/0247047 A1
(43) Pub. Date: Jul. 31, 2025

(54) ELECTRIC GENERATOR, CONVERSION METHOD AND METHOD FOR USING ONE SUCH GENERATOR

(71) Applicant: POMA, Voreppe (FR)

(72) Inventor: Mathieu BABAZ, Voreppe (FR)

(73) Assignee: POMA, Voreppe (FR)

(21) Appl. No.: 19/037,906

(22) Filed: Jan. 27, 2025

(30) Foreign Application Priority Data
Jan. 25, 2024 (FR) 2400753

(51) Int. Cl. H02S 30/20

(52) U.S. Cl. CPC H02S 30/20

(57) ABSTRACT

An electric generator comprises solar modules, a station and an additional station connected by a hauling cable supporting the solar modules and a hauling cable moving the solar modules. Each solar module is attached to the hauling cable by a detachable connector. A station is provided with means for moving the hauling cable to move the solar modules along the loop with respect to the station. A control circuit is configured to move the solar modules from a production position to a rest position by moving the hauling cable.

### BACKGROUND OF THE INVENTION

The invention relates to an electric generator, to a conversion method and to a method for using one such electric generator.

### PRIOR ART

To limit the consumption of fossil energies, a desire exists to use solar panels more intensely. However, it is not always easy to find surfaces suitable for receiving solar panels. The document U.S. Pat. No. 4,154,221 proposes to place the solar panel on a support structure that allows the tilt angle of the solar panel to be adjusted to adapt to the latitude of the installation and enables the solar panel to swivel to track the sun. This configuration is rather impractical as it results in a large ground surface occupation.

It is known to use shading systems formed by solar panels erected in fixed manner on a rigid structure, for example a parking area as illustrated in the document JP2014-122493. It is also known from the documents EP2669594 or WO2017/093540 to form a mobile shading system. The structure of the shading system comprises cables or rails extending along the parking area. By pulling on a hauling cable, a set of solar panels associated to one another by hinges is unfolded or folded up. In the folded position, the multiple solar panels are arranged against one another inside a container.

It is also known from the document FR3099861 to form a shading system above agricultural plots or livestock farms. Depending on the configurations, the solar panels are fixed to poles or are installed stationary to cables that run along the agricultural plot. The solar panels are installed able to swivel with respect to the cables to adjust the quantity of solar radiation the trees and crops are to receive.

It is further known to install solar panels above water bodies, for example lakes or rivers. There again, it is possible to run cables from one bank to the other and to mount the solar panels on floats. Such a teaching is presented in the documents FR3016686 or JP2004-235188.

These last three examples of embodiments enable more or less large surfaces to be used. However, these three examples are also characterised by a difficulty of implementing maintenance operations, for example after an intense climatic episode, in particular after a hailstorm, to repair a damaged solar panel. The area situated underneath the solar panels is in fact used or is impractical, which makes it complicated to set up a large-scale maintenance operation quickly. The same is the case when the solar panels are installed above a precipice, which requires substantial intervention means.

In installations where the solar panels are arranged in almost fixed manner on a support formed by cables, it is known to fold the solar panels to modify the tilt angle of the collection surface to facilitate removal of rainwater or snow. Such an embodiment is illustrated in the document WO2013/044404. A part of the panels is mounted fixed whereas the other part is able to be moved by means of a mobile cable thereby enabling the angle of the collection surface to be defined with respect to a reference direction.

According to another operating mode, the solar panels are installed on a netting that extends mainly in the vertical direction. The solar panels are arranged in rows and columns at the surface of the netting. The solar panels are mounted swiveling to track the sun within any one column. The ground surface occupation is considerable and the highest solar panels are difficult to access.

A support structure also exists formed by pillars connected by two cables arranged parallel to one another. The solar panels are fixed to the cable at each of their ends. Maintenance operations are complicated to implement.

It is further known to attach solar panels to one or more cables forming the support part. The support can comprise two cables that are offset from one another so as to define the tilt with respect to a horizontal plane. The cables are fixed on pillars of a cableway system above the cable hauling the vehicles. Such an embodiment is presented in the documents US2011/0155218 and WO2015/169396.

Document ES 1295389 provides an example of a system in which two support cables extend continuously in a straight line from a first anchorage to a second anchorage. Frames are installed to move along the two support cables by means of wheels arranged at the four corners of the frame and rolling on the two support cables. The frames are attached to two tractor cables that extend from one anchorage to the other. Multiple photovoltaic panels are arranged on the frames to capture solar radiation. The frames are installed on the support cables and then manually hooked together. This technical solution appears complicated to manage, as all the frames have to be installed and removed manually from an anchorage point. If a photovoltaic panel fails, it is necessary to remove or dismantle any frames located between the failed panel and the anchor. When weather conditions worsen, it is also advisable to intervene on the frames to avoid overloading the cables.

### OBJECT OF THE INVENTION

One object of the invention consists in providing an electric generator having a reduced ground surface occupation while enabling easy management of the multiple solar modules used, in particular when performing maintenance and/or replacement operations.

This issue tends to be solved by means of an electric generator comprising:
solar modules each defining a collection surface designed to collect solar radiation;
a station provided with a pulley;
a return pulley;
at least one aerial cable connecting the pulley and the return pulley to define a loop, the at least one aerial cable comprising at least one carrying cable designed to support the solar modules and at least one hauling cable designed to move the solar modules;
a movement device configured to move the at least one hauling cable and to move the solar modules along the loop with respect to the at least one station;
a control circuit configured to move the at least one hauling cable and to move at least one of the solar modules from a production position to a rest position located in the station.

The electric generator is remarkable in that the electric generator further comprises a plurality of connectors, each solar module being fixed to said at least one hauling cable by means of at least one connector, and in that the connectors are detachable connectors to detach the at least one hauling cable and the solar modules in the station.

In advantageous manner, the at least one carrying cable is also the at least one hauling cable.

In a particular configuration, each solar module is attached to the hauling cable independently of the other solar modules by at least one connector.

Preferentially, the solar modules are mounted movable with respect to one another in at least one direction perpendicular to a longitudinal axis of the at least one aerial cable by deformation of the at least one aerial cable.

According to one embodiment, each solar module is connected to the connector by an arm, the arm being able to swivel freely with respect to the connector to follow the gravity vector independently of the incline of the at least one carrying cable and to freeze the tilt angle of the collection surface with respect to the vertical direction.

In preferential manner, each solar module comprises a swivel device configured to make the collection surface swivel with respect to the arm and to the connector and to adjust a tilt angle of the collection surface of the solar module with respect to a vertical direction in the production position, adjustment being performed in at least one direction.

Advantageously, adjustment is performed in two orthogonal directions.

In a particular embodiment, the control circuit is provided with or connected to a meteorological module and configured to modify the tilt angle of the collection surface on receipt of a signal representative of predefined weather conditions consisting of wind speeds higher than a threshold speed, a hailstorm, a snowfall, or a rainy spell.

In a preferential development, at least one of the solar modules is attached to the aerial cable by two detachable connectors. At least one of the solar modules is foldable by means of at least one swivel connection arranged between two solar panels each connected to said at least one hauling cable by a detachable connector to increase or reduce a length of the at least one of the solar modules by folding between the two detachable connectors between the rest position and the production position, the length of the solar module being measured in the longitudinal direction of the at least one aerial cable or a direction of movement of the solar module.

In an advantageous configuration, the station defines at least one storage facility designed to store at least a part of the solar modules disconnected from the at least one aerial cable in the rest position.

In a particular embodiment, the electric generator comprises an additional station provided with the return pulley and located at a different altitude from the station. The additional station defines at least one storage facility designed to store a part of the solar modules. In a rest state, a first part of the solar modules is stored in the station and a second part of the solar modules is stored in the additional station, the solar modules being divided between the two strands of the at least one aerial cable, the solar modules in the production position being arranged on two strands of the loop connecting the station and the additional station.

In a preferential development, the control circuit is provided with or connected to a meteorological module and configured to move the solar modules from the production position to the rest position on receipt of a signal representative of harsh weather conditions consisting of wind speeds higher than a threshold speed, a hailstorm, or a snowfall.

In advantageous manner, at least one strand of the hauling cable forms a left-hand bend and/or a right-hand bend in a vertical observation.

Preferentially, the at least one carrying cable defines two strands that extend in a straight line between the station and the additional station. The solar modules are arranged under the at least one carrying cable. The solar modules are arranged divided between the two strands of the at least one aerial cable.

In an advantageous embodiment, several of the solar modules are connected to two adjacent solar modules at both of their ends in the longitudinal direction of the at least one aerial cable. The solar module is connected to said adjacent solar module by a pivot link.

Preferentially, the solar modules are attached to said at least one aerial cable by two connectors arranged at the opposite ends of the solar module in the longitudinal direction to form two end connectors. The end connectors attach two adjacent solar modules. The two adjacent solar modules are connected by a pivot link.

Advantageously, the adjacent solar modules extend continuously from the station to the additional station.

It is a further object of the invention to provide a method for converting a cable transport installation into an energy generator.

This object tends to be achieved by means of a method for converting a cable transport installation into an energy generator according to any one of the foregoing configurations:
providing a cable transport installation comprising vehicles, a station and an additional station connected by at least one carrying cable designed to support the vehicles and at least one hauling cable designed to move the vehicles, the hauling cable forming a loop, the carrying cable and hauling cable being aerial cables, each vehicle being fixed to the hauling cable, the installation also comprising a movement device of the at least one hauling cable to move the vehicles along the loop with respect to the at least one station;
replacing the vehicles by solar modules;
   and wherein a control circuit is configured to move the solar modules from a production position to a rest position by moving the at least one hauling cable.

It is a further object of the invention to provide a method for using an energy generator that is easier to operate than the configurations of the prior art.

This object tends to be achieved by means of a method for using an energy generator according to any one of the foregoing configurations comprising the following step:
moving the hauling cable to move at least one of the solar modules from a production position to a rest position.

### BRIEF DESCRIPTION OF THE DRAWINGS

Other advantages and features will become more clearly apparent from the following description of particular embodiments and implementation modes of the invention given for non-restrictive example purposes only and represented in the appended drawings, in which:

FIG. 1 schematically illustrates a view of an electric generator;

FIG. 2 schematically illustrates a view of a first embodiment of a solar module with a grip attached to a carrying-hauling cable;

FIG. 3 schematically illustrates a view of a second embodiment of a solar module with two detachable grips attached to a carrying-hauling cable;

FIG. 4 schematically illustrates a view of a third embodiment of a solar module with two detachable grips attached to a hauling cable and sheaves running on a carrying cable;

FIG. 5 schematically illustrates a view of a fourth embodiment of a solar module with two detachable grips attached to a hauling cable and sheaves running on two carrying cables;

FIG. 6 schematically illustrates a view of a fifth embodiment of a set of several solar modules that are mounted foldable with respect to one another, the right-hand end of the set being connected to the hauling cable by a detachable connector and the left-hand end being connected to a support.

### DESCRIPTION OF THE EMBODIMENTS

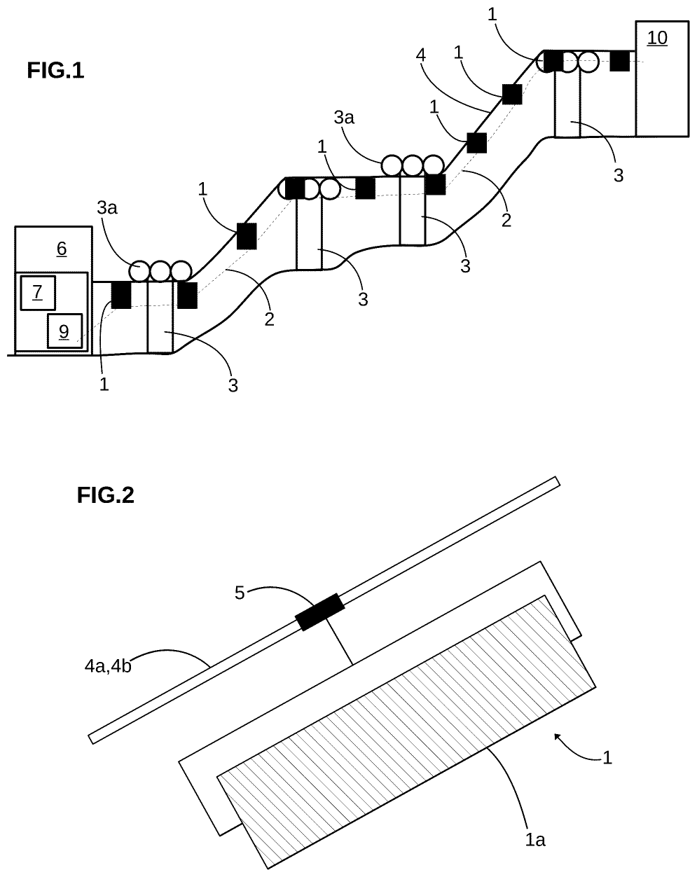

FIG. 1 illustrates an embodiment of an electric generator that is a solar electric generator. The electric generator comprises a plurality of solar modules 1. Each solar module 1 has one or more solar panels 1a that comprise a solar radiation collection surface. The solar radiation received by each solar panel 1 is transformed into an electric current. The solar panel(s) 1a define a solar radiation collection surface with a radiation capture plane that can be the plane defined by the upper surface of the solar panel 1a.

Preferentially, the electric current produced by each solar module 1 is routed to an electric output terminal via at least one electrical connection 2. As an alternative or as a complement, each solar module 1 is connected to a battery.

The at least one aerial cable 4 is arranged at a height above the ground in order not to prevent the ground situated underneath solar modules 1 from being utilised. The at least one aerial cable 4 has a carrying cable 4a and a hauling cable 4b. What is meant by a carrying cable 4a is at least one carrying cable 4a, for example two carrying cables 4a. What is meant by a hauling cable 4b is at least one hauling cable 4b, for example two hauling cables 4b.

The electric generator has a station 6 and an additional station 10 both equipped with a pulley. The pulleys collaborate with the hauling cable 4b to form a loop. The hauling cable 4b can be divided into two distinct strands that are bounded by the station 6 and the additional station 10. The loop defines the running track of solar modules 1 between the station 6 and the additional station 10. The electric generator can comprise more stations and the loop can be of any shape.

The electric generator is provided with a drive device 7 that is configured to move the hauling cable 4b. The hauling cable 4b moves with respect to the stations, thereby moving the solar modules 1 along the loop towards or away from the station 6 or the additional station 10. For example, the drive device 7 operates in conjunction with pulleys forming a drive wheel that is driven in rotation. The drive device 7 preferentially comprises a motor.

The at least one carrying cable 4a is designed to carry or support the different the solar modules 1. The at least one hauling cable 4b is designed to move the different the solar modules 1. The at least one hauling cable 4b defines the cable loop. The solar modules 1 are attached to the hauling cable 4b one behind the other over at least a part of the loop and preferably over the whole length of the loop. The connectors 5 can make a complete turn of the loop from the station 6 through the additional station 10 to the station 6, or from the additional station 10 through the station 6 to the additional station 10. The connector 5 passes successively from the first strand to the second strand or from the second strand to the first strand. The movement of a connector hooked to the first strand corresponds to the equivalent movement of a connector 5 hooked to the second strand. As they pass through the station 6 or the additional station 10, the connectors 5 are pulled along by the tractor cable or the support 6a, depending on the portion of the station 6 or the additional station 10 receiving the connector.

In preferential manner, the electric generator has one or more pillars 3 that are designed to support the hauling cable 4b and/or the carrying cable 4a. The loop can define a straight line between the station 6 and the additional station 10. It is also possible for the aerial cable 4 that connects the station 6 to the additional station 10 to define a change of direction, for example a right-hand or left-hand bend in a vertical observation.

Preferentially, the at least one aerial cable 4 is arranged at a height such that the distance between the ground and the nearest solar module 1 allows a vehicle or a person to pass. For example, the distance is more than 3 metres. Attaching the solar modules 1 on the aerial cable 4 enables the solar modules 1 to be installed at a height thereby avoiding occupying the ground surface between the stations and possibly between the pillars 3. This arrangement enables people, animals or vehicles to move between two pillars 3 including when the solar modules 1 are producing electricity. Underneath the aerial cable 4 and the solar modules 1, there can be a water body, a river, a precipice, or a traffic route, for example a road for motor vehicles or a railway. It is also possible for there to be a building, for example a house, an apartment block or an industrial building.

The electric generator is provided with a plurality of connectors 5 that perform connection between the at least one aerial cable 4 and the solar modules 1. The connector 5 is equipped with a first connection module that provides the connection between the solar module 1 and the carrying cable 4a. The first connection module can be in any form, for example a sheave 8, a hook, a slide or any other component that is able to slide or roll along the carrying cable 4a.

The connector 5 is provided with a second connection module that performs connection between the solar module 1 and the hauling cable 4b. The second connection module can be in any form, for example a grip or any other means able to be attached to the hauling cable 4b to drive the solar module 1 to move the latter towards or away from the station 6. A movement towards the station 6 corresponds to a movement away from the additional station 10 and vice versa in the longitudinal direction of the hauling cable 4b.

Depending on the embodiments, the electric generator can comprise one or more carrying cables 4a and one or more hauling cables 4b. Each solar module 1 is attached to one or more hauling cables 4b by means of at least one connector 5 of the plurality of connectors 5.

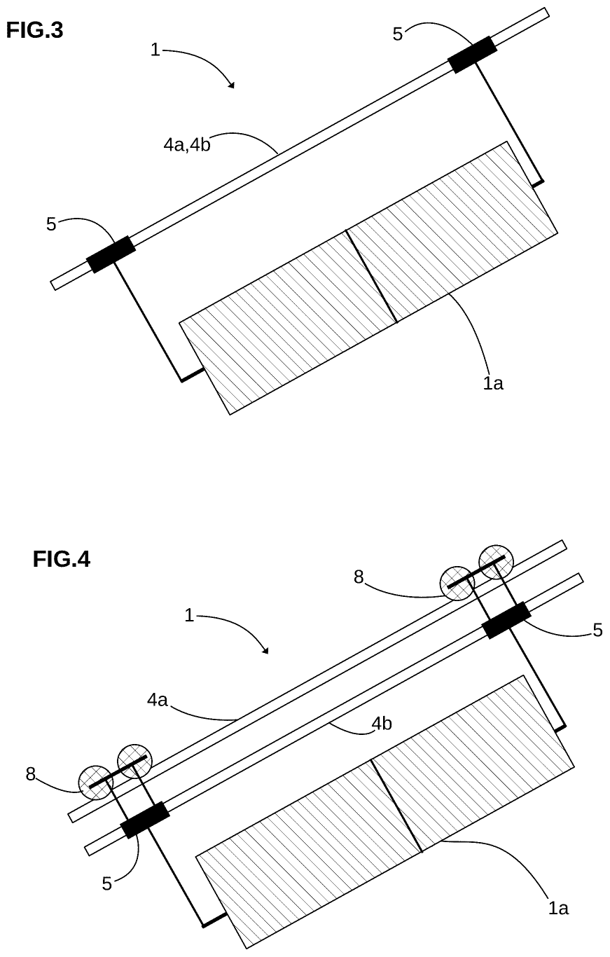

In one embodiment, the hauling cable 4b is also a carrying cable 4a, and the connector(s) 5 are preferentially formed by grips that can be the sole mechanical connection between the solar module 1 and the aerial cable 4. Advantageously, in this particular case, there is only one aerial cable 4. FIGS. 2 and 3 illustrate an embodiment wherein the solar module 1 is attached to a single aerial cable 4 that is a carrying-hauling cable. FIG. 2 illustrates attachment by means of a single grip. FIG. 3 illustrates attachment by means of two grips.

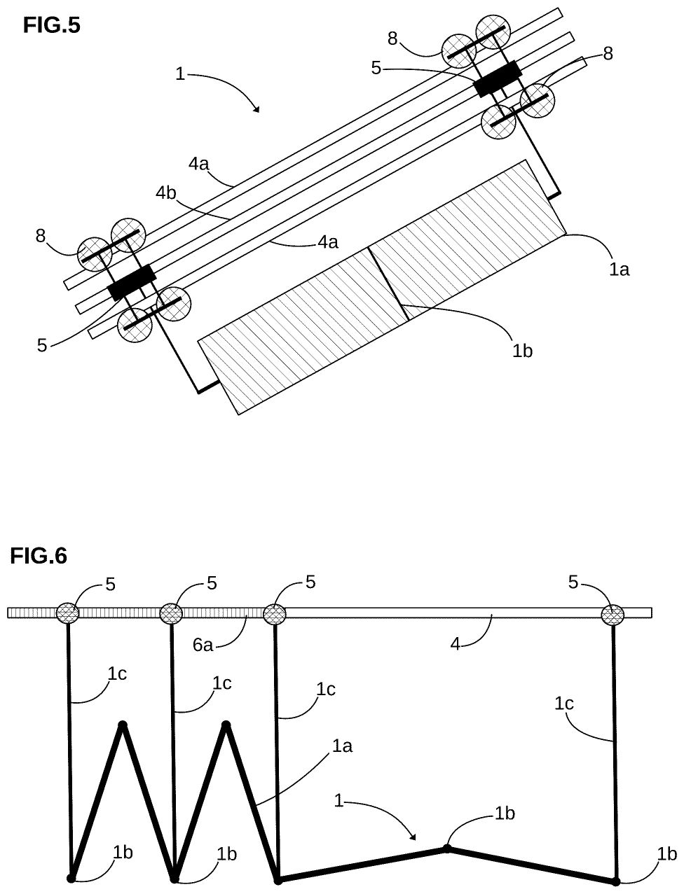

It is also possible to provide for the at least one aerial cable 4 to have several carrying-hauling cables, for example two carrying-hauling cables. It is further possible to provide for aerial cables 4 to have one or more carrying cables 4a that are distinct from the hauling cable(s) 4b. FIGS. 4 and 5 illustrate attachments with one hauling cable 4b and one or more carrying cables 4a.

Movement of the at least one hauling cable 4b moves the solar modules 1 along the loop with respect to the station 6 and with respect to the pillars 3 in the longitudinal direction of the aerial cable 4. The drive device 7 enables the solar modules 1 to be moved towards the station 6 or away from the station 6.

Movement of the at least one hauling cable 4b moves the solar modules 1 between a production position and a rest position. In the production position, the solar module 1 is located at a distance from the station 6 in an area where it is able to receive solar radiation and therefore to generate electric current. In the production position, the solar module 1 is stopped, i.e. the hauling cable 4a does not move driven by the drive device 7.

In the rest position, the solar module 1 is more easily accessible than in the production position, for example the solar module 1 is located less than 1.5 m from the ground to facilitate operations without a ladder, scaffolding or equipment for working at a height. Preferentially, the rest position is a position where the solar module is in the station 6.

The solar module 1 is arranged in a storage area, for example a storage facility designed to protect the latter from inclement weather conditions, or in a maintenance area, for example a storage facility in which a maintenance operation on the solar module 1 is easier than in the production position. Preferably, the storage area reduces or blocks capture of natural light radiation.

In preferential manner, the storage area is an area of the station 6. Preferentially, the same is advantageously the case for the maintenance area.

The solar modules 1 are mounted movable so as to be able to move between the production position and the rest position.

As indicated in the foregoing, in the production position, the solar modules 1 are installed at a height thereby making maintenance operations complicated or even impossible. It would appear complicated to perform a maintenance operation on panels located above a precipice, a water body or a traffic route. Furthermore, an operation at a height requires the installation of safety devices to protect the operating personnel as well as people who might be passing underneath or near the solar module 1 involved in the operation.

Finally, as maintenance requires a complex operating protocol to be set up, it cannot be performed quickly, for example following detection of malfunctioning on one of the solar modules. It is therefore particularly advantageous to be able to move each solar module 1 to a maintenance operation area that is preferentially the station 6 or the additional station 10. Performing the operation in the rest area means that the solar module 1 can be moved down towards the ground and be protected from external weather conditions if required.

The electric generator can have pillars 3, one or more aerial cables 4 and a drive device 7 configured to drive aerial cable(s) 4 that can be identical to those used in cable transport installations, for example those used in the mountains and/or in urban transport systems. The pillars 3 are preferentially equipped with sheaves 3a that support or compress the at least one aerial cable 4. These technologies are well mastered making a dependable and economic installation easy to achieve.

In the production position, the solar modules 1 are not designed to move which limits electricity consumption and makes the installation advantageous from an energy standpoint. In their production positions, the solar modules 1 are all attached to the hauling cable 4b and are spaced apart by a set distance that can be different between each group of two consecutive solar modules 1. In the production position, the connectors 5 are attached in fixed manner to the hauling cable 4b.

In a particular embodiment, the solar modules 1 are mechanically dissociated from one another. In other words, the solar modules 1 are arranged at certain distances from one another and are only connected by the carrying cable 4a and the hauling cable 4b. The carrying cable 4a and the hauling cable 4b form a flexible connection that enables a solar module 1 to move with respect to the other solar modules 1 in at least one direction perpendicular to the longitudinal direction of the carrying cable 4a, and preferably that enables a solar module 1 to move with respect to the other solar modules 1 in several directions perpendicular to the longitudinal direction of the carrying cable 4a.

When the solar modules 1 are exposed to the wind, the carrying cable 4a and the hauling cable 4b can deform to absorb the induced stresses. This construction limits the stresses on the solar modules 1 that sustain the wind load thereby facilitating electricity production even when a strong wind is blowing. The occurrence of conditions requiring the solar modules 1 to be moved from the production position to the rest position is thus reduced. In preferential manner, the solar modules are connected to the immediately adjacent solar modules 1 via an electric connection that is also a flexible connection.

This configuration is more advantageous than the one disclosed in the documents US2011/0253193, US2016/0173025, WO2017/093540 and EP2669594 where each solar module is connected to its two neighbouring modules by a hinge assembly, which implies transmission of stresses between the modules. When the solar modules are exposed to the wind, the latter applies stresses that are different in both their intensity and their direction with respect to the solar panels. The hinges and solar modules are subjected to large stresses to preserve the mechanical cohesion of the assembly. This also results in large stresses being applied on the support structure. When a strong wind is blowing, the solar modules have to be folded up.

On the contrary, the use of a flexible connection between the solar modules 1 reduces the forces applied in the solar modules 1 and on the support structure as a whole. It is then possible to use the production position for wind speeds that are higher than in the prior art configurations without increasing the mechanical stresses on the pillars 3 and on the station 6 and the additional station 10.

The electric connection 2 is preferentially a flexible connection, preferably more flexible than the carrying cable 4a, preferably more flexible than the carrying cable 4a and the hauling cable 4b.

As the solar modules 1 are independent of one another and are connected by an electric connection 2, in case of malfunctioning of the solar module 1 or of its electric connection 2, the malfunctioning solar module 1 can be moved to the rest position to perform the necessary repairs.

In a particular embodiment, the solar module is replaced by another solar module when an operation is performed in the station. In another embodiment, the solar module 1 is associated with the carrying cable 4a and with the hauling cable 4b by means of a connector 5 that is a detachable connector. On arrival in the station, the solar module 1 is electrically disconnected and the assembly formed by the connector 5 and the solar module 1 is detached from the aerial cable(s) 4. This enables a malfunctioning solar module 1 to be quickly removed or replaced. The storage area can be provided with one or more spare solar modules 1.

Detachment makes it possible to have a different speed and/or different directions between the connector 5 and the hauling cable 4b. In a particular embodiment, the connector 5 can be fitted with a clamp that defines a closed position and an open position. In the closed position, the clamp is fixedly attached to the hauling cable 4a, and in the open position the hauling cable 4b is able to move freely relative to the clamp. The clamp can be connected to an actuator, for example in the form of a lever, which acts on the clamp to define its state between the closed position and the open positions. The station 6 may be provided with a guide that acts on the actuator to place the clamp in the open position when the connector 5 reaches a predefined zone of the station 6. When the connector 5 reaches the predefined zone, the clamp opens and the photovoltaic module 1 is no longer driven by the aerial cable. The connector 5 is driven by a support 6a, which moves the photovoltaic module 1 at a different speed and/or in a different direction. The support 6a drives the photovoltaic module 1 from the predefined area to the storage area. The photovoltaic module moves from the production position to the rest position. The photovoltaic module can travel the opposite way from the rest position to the production position. The photovoltaic module moves along the support 6a until it reaches the predefined zone. The actuator is no longer acted upon by the guide and the clamp closes. In the closed position, the clamp securely mounts the connector with the tractor cable, enabling the photovoltaic module to be moved to its production position. The use of a detachable clamp enables an automated transition between the rest position and the production position, i.e. without the need for an operator to act directly on the connector, as is the case in the prior art. Passing through the station 6 or the additional station 10 to move the photovoltaic modules 1 between the first and second strands reduces the number of photovoltaic modules to be removed from the overhead cable in the event of maintenance work.

It is also possible to remove the malfunctioning solar module 1 and to attach other solar modules 1 in place of the malfunctioning solar module 1, or to leave the space free and replace it by an extender to be able to fit the electric connection 2.

Furthermore, during a maintenance operation, all or part of the other solar modules 1 can be kept in a production position. Modification of one or more electric connections 2 can be performed before proceeding with the maintenance operation. Such an embodiment enables the up-time of the electric generator to be increased.

In a particular embodiment, the electric generator is provided with a storage area that is designed to store all or part of the plurality of solar modules 1. The storage area is preferably a part of the station 6. In the rest position, the solar module 1 is detached from the aerial cable 4, i.e. from the hauling cable 4b and the carrying cable 4a. An operation can be performed on the cable without having to perform an additional operation on the solar modules 1.

The electric generator is provided with a control circuit 9 connected to the drive device 7 so as to control the movement of the solar modules 1 between the production position and the rest position by moving the hauling cable 4b.

The use of the solar modules 1 that are mechanically dissociated from one another other than by the hauling cable 4b and the electric connection 2 is particularly advantageous when the aerial cable 4 does not define a straight line between the station 6 and the additional station 10 in a vertical observation, i.e. with a right-hand bend or a left-hand bend.

In another embodiment, the solar modules 1 are mechanically connected directly behind one another by connecting members that define pivot links. The swivel axis is perpendicular or substantially perpendicular to the longitudinal axis of the aerial cable 4. The swivel axis is preferentially horizontal or substantially horizontal.

The use of pivot links enables the footprint of the set of the solar modules 1 in the longitudinal direction to be adjusted. The pivot link makes it possible to deal with differential expansion phenomena between connectors 5 attached to the hauling cable 4b and the solar modules 1.

The use of pivot links is particularly advantageous in association with detachable connectors that enable the aerial cable 4 to be detached in the station 6 or in the additional station 10.

When the hauling cable 4b moves to drive the solar module(s) 1 from the production position to the rest position, the solar modules 1 enter the station behind one another. To reduce the space occupation of the solar modules 1 in the storage area, it is advantageous to fold the solar modules 1 against one another. Detachment of the detachable connector from the hauling cable 4b onto a support 6a, for example a rail, results in a speed reduction. The speed reduction results in the part of the assembly fixed to the support 6a moving less quickly than the hauling cable 4b attached to the rest of the assembly. This generates a force on the solar module 1 that tends to fold.

As illustrated in FIG. 6, the folding is progressively spread to the whole set of the solar modules 1 as the latter move from the hauling cable 4b to the support 6a. The reverse movement enables the solar modules 1 to be unfolded taking advantage of the force induced by the hauling cable 4b that moves more quickly than the connector attached to the support 6a. This embodiment is particularly advantageous when the path followed by the set of the solar modules 1 is a straight line, which simplifies the configuration of the pivot link.

A set of the solar modules 1 can be formed by two or more solar modules 1. Preferably, a set of solar modules 1 is formed by half of the solar modules or by all of the solar modules 1. When the set of solar modules 1 comprises half of the solar modules, it is advantageous to have two distinct assemblies that are attached to the two strands of the hauling cable 4b separated by the station 6 and the additional station 10.

The solar modules 1 are each connected to the aerial cable 4 by at least one connector 5. In one embodiment, a connector 5 is attached to each of the two ends of the solar module 1 in the longitudinal direction of the aerial cable 4 when the solar module 1 is in the production position. The connectors 5 are preferentially attached to the ends of two adjacent solar modules 1. In an alternative, the connector 5 is fixed to a central part of the solar module 1.

In this embodiment, it is advantageous for the central part of the solar module 1 to be provided with a pivot link and for the ends connected to the adjacent solar modules 1 to also be provided with a pivot link. The solar module 1 can be broken down into two solar panels connected by a pivot link.

It is also possible to provide the solar modules 1 that are connected to the aerial cable 4 by two detachable connectors 5 arranged at the two ends of the solar module 1 in the longitudinal direction when the solar module 1 is in the production position. Each solar module 1 is dissociated from the others. The solar module 1 has a pivot link in its central portion that enables the solar module 1 to be folded or unfolded. The speed difference that exists between the detachable connector 5 associated with the support 6a and the detachable connector 5 associated with the hauling cable 4b enables the solar module 1 to be folded or unfolded. The space occupation is different between the rest position and the production position.

In more general manner, to perform storage of the solar modules 1 under advantageous conditions, it is beneficial for the solar modules 1 to be attached by means of one or more detachable connectors 5 and for the solar module 1 to be foldable.

The detachable connector 5 can be a grip well known in the cable transport field, in particular the field of transporting of goods or moving people preferably via an aerial cable. It is advantageous for the station 6 to have a rail or any other equivalent support device that connects the hauling cable 4b and the storage area so as to be able to detach the solar module 1 from the hauling cable 4b to move the latter to the storage area.

In preferential manner, the control circuit 9 is provided with or connected to a meteorological module. The meteorological module receives and/or computes information relative to meteorological data.

For example, following detection of inclement weather conditions, the control circuit 9 of the electric generator can command storage of at least a part of the solar modules 1 or even all the solar modules 1 in the rest position. In a particular embodiment, a signal representative of inclement weather conditions is chosen from a signal representative of a hailstorm, a violent wind episode, or a snowfall. The same can be the case following detection of a signal representative of a thunderstorm with lightnings. In the latter case, a single intervention on the electric circuit can be envisaged to isolate the solar modules 1 electrically.

In a particular embodiment, in the production position, the solar modules 1 are mounted movable with respect to the connector 5. Preferentially, the solar modules 1 are mounted able to swivel so that the plane of the solar panel 1a designed to collect the solar radiation can adjust its tilt value with respect to the vertical direction or to the North-South direction to move the solar radiation collection surface and track the path of the sun. The control circuit 9 can be configured to adjust the tilt angle of the solar radiation collection plane throughout the day to track the sun. Adjustment can be independent for each solar module 1. Adjustment can be performed by means of a motor fixed to the connector 5 and to the solar module 1.

The three-dimensional orientations of the different portions of the carrying cable 4a and the hauling cable 4b are known between the station 6 and the additional station 10. The position of the different pillars 3 is known. The three-dimensional orientations of the aerial cable 4 comprise its angular deviation from the North-South direction and its angular deviation with respect to the vertical. The shadow provided by a pillar can also be calculated according to the path of the sun. This information enables the position of solar modules between the station 6 and the additional station 10 to be calculated to optimise the solar radiation collection efficiency. This information is also usable to define a personalised tilt angle for each solar module 1 and to adjust the tilt values if the hauling cable 4b moves.

In a particular embodiment, the position of each solar module 1 with respect to a reference point is determined, for example by calculating the length of movement of the hauling cable 4b from the reference point. It is then possible to know the position of each solar module 1 and therefore the angular deviation that exists with respect to the North-South direction based on the orientation of the aerial cable 4. Once the solar module 1 has been installed in the production position, the control circuit 9 can compute the position of the solar module 1 along the loop of the hauling cable 4b and adjust the tilt angle of the solar module 1 with respect to the North-South direction.

In one embodiment, the solar module 1 has an arm 1c that is mounted able to swivel freely with respect to the carrying cable 4a so as to be aligned with a reference orientation independently of the incline of the carrying cable 4a with respect to the vertical direction. Preferentially, the arm 1c is mounted able to pivot freely to follow the gravity vector using the weight of the solar module 1. Such an embodiment enables a reference plane to be had for the solar module 1 that is independent of the incline of the carrying cable 4a. The reference plane is for example a horizontal plane.

Such an embodiment is particularly advantageous when the electric generator extends over a terrain that is not horizontal. For example, the generator is provided with several pillars 3 and the incline of the carrying cable 4a varies between two successive pillars 3. The arm 1c enables the influence of the incline of the carrying cable 4a on the collection performances of the solar module 1 to be eliminated or reduced. Over a large distance, the carrying cable 4a deforms. It is therefore preferable to have an arm 1c that compensates the uncertainties regarding the incline. When the two opposite strands of the carrying cable 4a are used, the position of the carrying cable 4a with respect to the ground varies according to the weight applied on the carrying cable 4a, i.e. according to the number of solar modules 1 installed. The arm 1c enables the influence of a change in the number of solar modules installed and/or a modification of the weight of the installed solar modules to be circumvented.

The use of such an arm 1c makes it easier to calculate the tilt of the collection surface to optimise the electricity production efficiency. For example, to track the sun, the control circuit 9 can calculate a tilt angle by only taking account of the angular deviation with respect to the North-South direction for each solar module 1. If the carrying cable 4a extends in a straight line in a vertical observation, the arm 1c enables the incline of the carrying cable 4a under its weight and the tilt of the solar modules 1 to be compensated.

In one embodiment, the tilt with respect to the vertical direction is largely variable according to the multiple positions accessible to the solar module 1 and the at least one arm 1c reproduces all or part of the tilt. Calculation of the exact position of the production position of the solar module 1 with respect to the reference point enables the control circuit 9 to calculate the tilt with respect to the vertical and the tilt with respect to the North-South direction and the tilt of the solar module 1 to be modified accordingly to improve the solar conversion efficiency.

As an alternative, the tilt angles of the collection surfaces with respect to the vertical and/or with respect to the North-South direction are defined individually for each solar module 1. The solar modules 1 are attached to the hauling cable 4b in precise positions, and the control circuit 9 calculates the movement of the hauling cable 4b to place the solar modules in the required position along the loop. The hauling cable 4b is moved so that the solar modules 1 are in the position corresponding to the tilt angles applied on collection surface 1a.

In a particular embodiment, the solar modules 1 are mounted able to swivel with respect to the connector 5. Following detection of conditions representative of a spell of harsh weather, the control circuit 9 can decide to modify the tilt angle of the solar modules 1 with respect to the vertical direction. For example, following detection of a snowfall and/or following detection of conditions announcing a hailstorm, it is advantageous to tilt the solar modules 1 so that the collection surface is vertical, i.e. so that the vector normal to the collection surface of the solar module 1 moves towards a horizontal direction, i.e. the edge of the solar panel extends vertically or mainly vertically. The same can be the case following detection of conditions announcing a spell of rain laden with sand or other particles that are liable to deposit on collection surface 1a of the solar module 1 and reduce the transmittance value.

In another embodiment, following detection of winds having a higher speed than a threshold value and/or following detection of conditions announcing a windy spell with winds having a higher speed than the threshold value, it is advantageous to tilt the solar modules 1 so that the exposure to the wind is lower and preferably as low as possible. It is advantageous for the vector normal to the surface of the solar module 1 to be close to a vertical direction.

These actions of the control circuit 9 can be engaged before performing storage of a part or all of the solar modules 1 in the storage area when the weather conditions worsen.

When the solar modules 1 are attached by means of a fixed connector and/or the electric generator is devoid of a storage area able to store at least 50% of the solar modules 1, it is advantageous to provide the solar modules 1 that are mounted able to swivel to adjust the tilt angle with respect to the vertical direction and/or with respect to the North-South direction in order to adjust the effects of the weather conditions, for example the wind exposure or the direction in which the rain, snow or hail is falling.

To increase the quantity of electric current to be produced, it is advantageous to increase the collection surface by increasing the length of the solar modules 1, i.e. the dimension in the longitudinal direction of the aerial cable 4. When the length of the solar modules 1 reaches a threshold value, it is advantageous to secure the solar modules 1 by means of two securing devices that are located at the two opposite ends of the solar modules 1 in the longitudinal direction of the aerial cable 4.

It is advantageous for the solar modules 1 to be attached to the aerial cable 4 by means of detachable connectors i.e. connectors that can be attached to or detached from the aerial cable 4. The connectors 5 can be produced using the same technologies as those used in cable transport installations and preferably installations of aerial cable car type.

When the solar module 1 is attached to the aerial cable 4 by at least two detachable connectors that are offset in the longitudinal direction or the direction of movement of the solar module 1, it is advantageous for the solar module 1 to have a variable length between the two detachable connectors. For example, the solar module 1 is folded or foldable with a hinge 1b defining a fold line that is secant to the longitudinal direction of the aerial cable 4 in an observation in a direction perpendicular to the longitudinal axis, for example a vertical direction. The solar module 1 has a first length when the connectors 5 are fixed to the at least one hauling cable 4b and a second length when the connectors 5 are detached from the at least one hauling cable 4b.

In the rest position, the solar module 1 occupies less space than in the production position. This configuration makes it possible to have a storage area of reduced size while being able to store all or part of the solar modules 1 with their connectors 5.

The use of a solar module 1 that is fixed to the aerial cable 4 only by two detachable connectors and has a variable length means that the latter can be stored more easily in a storage area and can pass more easily round a return pulley or a drive pulley. In addition to being foldable, the solar module 1 can be inclinable with respect to the vertical direction and/or the North-South direction.

In case of malfunctioning of a solar module 1 and/or its electric connection, it is possible to move the hauling cable 4b so as to move the malfunctioning solar module 1 from its production position to its rest position and then exclude it before re-attaching the other solar modules 1 if the latter were detached.

It is further possible to replace the solar module 1 by a replacement panel so that the electric generator maintains its required electric production. In the same way as for replacement or exclusion of a vehicle in a cable transport installation, replacement or exclusion of a solar module 1 can be performed in a very short time with little or no personnel.

In a particular embodiment, the electric generator is provided with an additional station 10 that is also provided with a storage area, for example a storage room. A part of the solar modules 1 is stored in the station 6 and another part of the solar modules 1 is stored in the additional station 10. This configuration is advantageous when the station 6 and the additional station 10 are installed at different altitudes to define a top station and a bottom station. Preferentially, one half of the solar modules 1 can be stored in the top station and the other half of the solar modules 1 can be stored in the bottom station. When moving from a rest position to a production position, it is advantageous for half of the solar modules 1 to move from the top station and the other half of the solar modules 1 to move from the bottom station.

The weight of the solar modules 1 moving from the top station helps the solar modules 1 move from the bottom station. As a corollary, when moving from the production position to the rest position, the weight of the solar modules 1 moving from the bottom station helps the solar modules 1 move in the direction of the top station. This greatly reduces the consumption of the drive device 7.

When the solar modules are attached with fixed grips, it is advantageous to stagger the modules evenly along the loop so that an increase of altitude of a number of solar modules attached to a strand of the hauling cable 4b results in a decrease of altitude for an equivalent number of solar modules attached to the other strand of the hauling cable. The stresses related to movement of the hauling cable are reduced.

In preferential manner, the solar modules 1 are attached to and detached from the aerial cable 4 independently of one another thereby making maintenance operations and adjustment of the electric generator to the weather conditions easier to perform. The solar modules 1 are connected to an electric current output terminal by means of an electric connection 2. In preferential manner, the solar modules 1 are connected to one another by means of an electric connection 2. In a particular embodiment, the electric connection 2 extends from the station 6 to each solar module 1 or a part of the solar modules 1. The other solar modules 1 are connected to the additional station 10 by another electric connection 2.

Modification of the number of the solar modules 1 attached to the aerial cable 4 can be performed easily by an action on the electric connection 2.

It is advantageous for the solar modules 1 to be attached independently from one another to the aerial cable 4. Preferentially, two adjacent solar modules 1 are connected by an electric connection 2, for example an electrically conductive cable. The electrically conductive cable can have a length that is greater than or equal to the distance separating two solar modules 1 or it can be elastically deformable.

It is advantageous for two solar modules 1 to be connected only by a flexible connection, for example the aerial cable 4 and possibly the electric connection 2 between the solar modules 1. The two solar modules 1 can move with respect to one another thereby being able to adjust better to wind forces. It is disadvantageous to connect several solar modules 1 with rigid connections that induce large stresses when the electric generator is exposed to wind.

The electric generator is designed to supply an electric power grid and/or an electrical load. The solar modules 1 can be connected in series or in parallel. The solar modules 1 can be connected independently from one another to the output terminal of the electric generator. As an alternative, the solar modules 1 are connected to one another, for example one behind the other. The last solar module 1 is connected to the output terminal.

In a particular embodiment, a cable transport installation can be converted into an electric generator. The solar modules 1 are attached to the aerial cable 4 by means of at least one connector 5. This enables the existing infrastructure of the cable transport installation to be used to attach the solar modules 1 thereto. The cable transport installation is provided with two stations that are connected by at least one hauling cable and at least one carrying cable. The hauling cable can be the carrying cable. The cable transport installation is provided with drive means, for example a motor, that are configured to drive the hauling cable that defines a loop connecting the station with the additional station in rotation.

The cable transport installation is provided with one or more vehicles, for example cars and/or chairs. The vehicles are initially attached to the aerial cable 4. The vehicles are detached from the aerial cable 4 and are replaced by the solar modules 1.

The cable transport installation can be a gondola lift, a chairlift, an aerial cable car, a funitel or un telemix/combi. The cable transport installation can be provided with detachable grips or fixed grips to attach the vehicles to the cables. It is advantageous to keep the same grip technology when transforming the cable transport installation into a solar electric power generator.

For example, a transport installation designed for winter activities or for one or more other periods can be converted into an electric generator during the rest of the year. This type of conversion can also be envisaged when the transportation activity of people or goods is stopped, making it possible to take advantage of infrastructures that have already been set up.

As the conversion is achieved by replacing the vehicles by solar modules, the conversion can be performed quickly.

Cableway systems are generally installed in places exposed to intense climatic conditions with violent winds, snow, hail and rain. The electric generator appears particularly suitable for these conditions as it enables solar modules to be had that are designed to withstand high wind speeds, and their tilt angle to be modified so as to be less sensitive to the effects of snow, hail and rain. The electric generator can operate with limited human intervention. It also enables a low electricity consumption to be had by reducing the occurrence of movement of the panels from the production position to the rest position. Furthermore, if the modules can be stored in the bottom station and in the top station, the electricity consumption is considerably reduced thereby greatly improving the energy balance of the electric generator.

For example, if a solar module 1 is considered to be malfunctioning, it is possible to move at least a part of the solar modules to the rest area and to intervene when the sun has set or when the radiation emitted is lower than a threshold value. Once the solar module is in the rest position, a maintenance operation can be performed or a replacement be made. The solar modules can then be re-installed in the production position for the next sun tracking.

When the solar modules are located above agricultural areas and/or above livestock farms, the operations are performed at a distance from the livestock farm or agricultural area.

1. Electric generator comprising:
solar modules each defining a collection surface designed to collect solar radiation;
a station provided with a pulley, the station defining at least one storage facility designed to store at least a part of the solar modules in a rest position;
a return pulley;
at least one aerial cable defining a loop connecting the pulley and the return pulley, the at least one aerial cable being designed to support the solar modules and comprising at least one hauling cable designed to move the solar modules attached to the at least one hauling cable;
a drive device configured to move the at least one hauling cable and to move the solar modules along the loop with respect to the at least one station;
a plurality of connectors, each solar module being fixed to said at least one hauling cable by means of at least one of the plurality of connectors;
a control circuit configured to command the drive device to move at least a part of the solar modules from a production position to the rest position, the production position being disposed between the pulley and the return pulley;
characterised in that the connectors are detachable connectors to detach the solar modules and the at least one aerial cable in the station, the station having a support device that connects the at least one hauling cable and the storage facility in order to be able to detach the solar module from the at least one hauling cable to move the solar module to the storage facility, the connectors moving at a different speed and/or in different directions with respect to the at least one hauling cable; the connectors running along a support device being disconnected from the at least one aerial cable in the rest position.

2. Electric generator according to claim 1 wherein the at least one hauling cable defines a loop divided into a first strand and a second strand each connecting the pulley and the return pulley, wherein in the production position a part of the photovoltaic modules is only attached to the first strand and another part of the photovoltaic modules is only attached to the second strand.

3. Electric generator according to claim 2 wherein the hauling cable is also at least one carrying cable supporting the photovoltaic modules in the production position.

4. Electric generator according to claim 1 wherein each solar module is attached to said at least one hauling cable by means of at least one specific connector, each solar module being movable in two directions perpendicular to a longitudinal direction of the aerial cable independently of the other solar modules.

5. Electric generator according to claim 4 wherein, in the production position, the adjacent solar modules are independently attached to the at least one hauling cable and are only connected by a flexible connection to be mounted movable with respect to one another in at least one direction perpendicular to a longitudinal axis of the at least one aerial cable by deformation of the at least one aerial cable.

6. Electric generator according to claim 5 wherein each solar module is connected to the connector by an arm, the arm being able to swivel freely with respect to the connector to follow a gravity vector independently of an incline of the at least one carrying cable and to freeze a tilt angle of the collection surface with respect to a vertical direction, the photovoltaic modules being arranged under the at least one carrying cable.

7. Electric generator according to claim 6 wherein each solar module comprises a pivot device configured to make the collection surface swivel with respect to the arm and to the connector and to adjust a tilt angle of the collection surface of the solar module with respect to a vertical direction in the production position, adjustment being performed in at least one direction.

8. Electric generator according to claim 7 wherein adjustment is performed in two orthogonal directions.

9. Electric generator according to claim 1 wherein the control circuit is provided with or connected to a meteorological module and configured to modify the tilt angle of the collection surface on receipt of a signal representative of predefined weather conditions consisting of wind speeds higher than a threshold speed, a hailstorm, a snowfall, or a rainy spell, the solar modules being in the production position and/or configured to move the solar modules from the production position to the rest position on receipt of a signal representative of adverse weather conditions consisting of wind speeds higher than a threshold speed, a hailstorm, or a snowfall.

10. Electric generator according to claim 1 wherein at least one of the solar modules is attached to the at least one hauling cable by two detachable connectors and wherein said at least one of the solar modules is foldable by means of at least one pivot link arranged between two solar panels each connected to said at least one hauling cable by a detachable connector to increase or reduce a length of the at least one of the solar modules by folding between the two detachable connectors between the rest position and the production position, the length of the solar module being measured in the longitudinal direction of the at least one aerial cable or a direction of movement of the solar module.

11. Electric generator according to claim 2 comprising an additional station equipped with the return pulley and located at a different altitude from the station, wherein the additional station defines at least one storage facility designed to store a second part of the solar modules and wherein, in a rest state, a part of the solar modules is stored in the station and a second part of the solar modules is stored in the additional station, the solar modules being distributed over the first strand and the second strand, the solar modules in the production position being arranged on the first strand and the second strand of the loop connecting the station and the additional station.

12. Electric generator according to claim 11 wherein several of the solar modules are connected at both ends to two adjacent solar modules in the longitudinal direction of the at least one aerial cable, wherein the solar module is connected to said adjacent solar module by a pivot link.

13. Electric generator according to claim 12 wherein the solar modules are attached to said at least one aerial cable by two connectors arranged at the opposite ends of the solar module in the longitudinal direction to form two end connectors, wherein the end connectors attach two adjacent solar modules and wherein the two adjacent solar modules are connected by a pivot link.

14. Conversion method of a cable transport installation into an energy generator according to claim 1 comprising the following steps:
providing a cable transport installation comprising vehicles, a station and an additional station connected by at least one aerial cable designed to support the vehicles and comprising at least one hauling cable designed to move the vehicles, the hauling cable forming a loop, each vehicle being attached to the hauling cable, the installation also comprising a movement device of the at least one hauling cable to move the vehicles along the loop with respect to the at least one station;
replacing the vehicles by the solar modules;
and wherein a control circuit is configured to move the solar modules from a production position to a rest position by moving the at least one hauling cable.

15. Method for using an energy generator according to claim 1 comprising the following step:
moving the hauling cable to move at least one of the solar modules from a production position to a rest position.
